(19) United States
(12) Patent Application Publication
(10) Pub. No.: US 2026/0316030 A1
(43) Pub. Date: Oct. 15, 2026

(54) APPARATUS FOR PROMOTING CHEMICAL REACTION OF A METAL OXIDE CATALYST USING MICROWAVE AND PLASMA AND A METHOD FOR PROMOTING CHEMICAL REACTION USING THE SAME

(71) Applicant: POSTECH RESEARCH AND BUSINESS DEVELOPMENT FOUNDATION, Pohang-si (KR)

(72) Inventors: Gunsu YUN, Pohang-si (KR); Jaemin YOO, Pohang-si (KR); Hyungyu JIN, Pohang-si (KR); Dongkyu LEE, Pohang-si (KR); Taehyeong KIM, Pohang-si (KR)

(73) Assignee: POSTECH RESEARCH AND BUSINESS DEVELOPMENT FOUNDATION, Pohang-si (KR)

(21) Appl. No.: 19/638,064

(22) Filed: Apr. 2, 2026

(30) Foreign Application Priority Data
Apr. 14, 2025 (KR) 10-2025-0048306

(51) Int. Cl. B01J 8/06; C01B 3/061

(52) U.S. Cl. CPC B01J 8/067; B01J 8/065; C01B 3/063; B01J 2208/00442; B01J 2208/065

(57) ABSTRACT

Provided are an apparatus for promoting a chemical reaction of a metal oxide catalyst using microwaves and plasma and a method for promoting a chemical reaction using the same, which are capable of producing hydrogen by reducing and oxidizing a catalyst member, which is a metal oxide, and performing water splitting under a relatively low temperature.

### CROSS-REFERENCE TO RELATED APPLICATIONS

This application claims priority to and the benefit of Korean Patent Application No. 10-2025-0048306, filed on Apr. 14, 2025, the entire contents of which are incorporated herein by reference.

### TECHNICAL FIELD

The present disclosure relates to an apparatus for promoting a chemical reaction of a metal oxide catalyst and a method for promoting a chemical reaction using the same, which are capable of producing hydrogen by reducing and oxidizing a catalyst member, which is a metal oxide, and performing water splitting using microwaves and plasma.

### DESCRIPTION OF RELATED ART

A representative chemical process utilizing a metal oxide catalyst includes a method for producing clean hydrogen by splitting water.

Conventional technologies for manufacturing hydrogen-based energy include hydrogen production technologies using hydrocarbons as a raw material, such as steam-methane reforming. This technology has an advantage in that hydrogen and carbon monoxide can be simultaneously produced in the form of syngas, which has high chemical utility value. However, there is a problem in that carbon dioxide is generated due to the carbon contained in the hydrocarbon itself.

As a conventional technology capable of solving such a problem of carbon generation, there is a hydrogen production method using electrochemical water splitting, which is a carbon-free green hydrogen production technology. In the electrochemical water splitting technology, alkaline water electrolysis, proton exchange membrane (PEM) water electrolysis, anion exchange membrane (AEM) water electrolysis, and solid oxide water electrolysis are mainly used. However, since most water electrolysis is based on surface reactions, there are constraints on the scaling up of the apparatus, making it difficult to meet the increasing demand for hydrogen production in the future.

As another conventional green hydrogen production technology, there is a two-step thermochemical water splitting hydrogen production method. This method utilizes a reaction between a metal oxide catalyst and steam in a high-temperature environment of 1300° C or higher and has an advantage of being suitable for mass hydrogen production based on a volumetric reaction.

However, since this method utilizes a joule heating method in which a current is passed through a heating element to maintain the entire reactor at a high temperature or a solar thermal collection method using a heliostat, heat loss due to maintaining the high-temperature environment is inevitable. Thus, improvement is required in terms of hydrogen production yield relative to energy consumption, and there are limitations in constructing a hydrogen production system due to constraints on the selection of heat-resistant materials for the reactor.

### SUMMARY

### Technical Problem

One embodiment of the present disclosure is to provide an apparatus for promoting a chemical reaction of a metal oxide catalyst using microwaves and plasma and a method for promoting a chemical reaction using the same, which are capable of producing hydrogen by reducing and oxidizing a catalyst member, which is a metal oxide, and performing water splitting under a relatively low temperature using microwaves and plasma.

### Solution to Problem

An apparatus for promoting a chemical reaction of a metal oxide catalyst according to an embodiment of the present disclosure can produce hydrogen by reducing and oxidizing a catalyst member, which is a metal oxide, and performing water splitting under a relatively low temperature using microwaves and plasma. The promoting apparatus may include: i) a cavity resonator configured to resonate electromagnetic waves of a predetermined frequency when the electromagnetic waves are introduced therein; ii) a glass tube, at least a portion of which passes through an interior of the cavity resonator; iii) a catalyst member disposed inside the glass tube, the catalyst member being a metal oxide; iv) a microwave irradiation unit for irradiating microwaves onto the catalyst member by passing the microwaves through the interior of the cavity resonator so as to selectively heat the catalyst member; v) a gas supply unit for selectively injecting an inert gas into the glass tube; and vi) a steam supply unit for selectively injecting steam into the glass tube.

The catalyst member may be placed in any one state of: i) a reduction reaction state in which the catalyst member is heated by being irradiated with the microwaves such that a predetermined amount of oxygen is released from the catalyst member and the catalyst member is reduced; and ii) an oxidation reaction state in which the catalyst member is cooled by not being irradiated with the microwaves such that a predetermined amount of oxygen released by water splitting is adsorbed onto the catalyst member and the catalyst member is oxidized. Hydrogen may be generated from the steam when the catalyst member is in the oxidation reaction state.

The promoting apparatus may further include a plasma unit for generating plasma to form a plasma region surrounding a portion of the glass tube so as to penetrate the portion of the glass tube with the plasma. The inert gas and the steam may contact the catalyst member via the plasma region when introduced into the glass tube.

A region where the microwaves resonate inside the cavity resonator may be defined as a resonance region. The catalyst member may be disposed inside the glass tube on the resonance region. The plasma unit may form the plasma region at a position spaced apart from the resonance region.

The microwave irradiation unit may irradiate the microwaves onto the catalyst member such that the catalyst member is placed in the reduction reaction state. The steam supply unit may inject the steam into the glass tube such that the catalyst member is placed in the oxidation reaction state.

The glass tube may include: i) a resonance part disposed inside the cavity resonator; ii) an inlet part extending from one end of the resonance part to an outside of the cavity resonator, through which the inert gas and the steam are introduced from the gas supply unit; and iii) an outlet part extending from the other end of the resonance part to the outside of the cavity resonator, through which hydrogen is discharged.

The catalyst member may be disposed inside the resonance part. The plasma unit may form the plasma region at the inlet part.

The plasma unit may include: i) a first metal electrode disposed spaced apart from one side of the inlet part; ii) a second metal electrode disposed spaced apart from the other side of the inlet part; and iii) a power application unit for applying power to the first metal electrode and the second metal electrode such that the plasma region is formed at the inlet part.

The gas supply unit may include: i) a gas supply part for supplying the inert gas to the glass tube; and ii) a gas channel providing a path through which the inert gas flows from the gas supply part to the glass tube.

The steam supply unit may include: i) a steam supply part for supplying the steam to the glass tube; ii) a steam channel connected to communicate with the gas channel from the steam supply part; and iii) an injection valve disposed in the steam channel and configured to be opened and closed such that the steam is selectively introduced from the steam supply part into the gas channel.

The catalyst member may include magnetite (Fe₃O₄), nickel ferrite (NiFe₂O₄), cobalt ferrite (CoFe₂O₄), magnesium ferrite (MgFe₂O₄), mixed metal ferrite ((MgNiCo)₀.₇₅Fe₀.₂₅O₁.₂), cerium dioxide (CeO₂), gadolinium-doped cerium dioxide (Gd₀.₂Ce₀.₈O₂), lanthanum strontium oxide (LaSrO₃), calcium titanate (CaTiO₃), barium manganate (BaMnO₃), and strontium titanate (SrTiO₃).

A method for promoting a chemical reaction of a metal oxide catalyst according to an embodiment of the present disclosure may include: i) arranging a glass tube and a catalyst member by positioning the glass tube such that a portion of the glass tube passes through an interior of a cavity resonator that resonates electromagnetic waves, and disposing the catalyst member inside the glass tube; ii) forming a plasma by forming a plasma region at a portion of the glass tube; iii) injecting a gas by injecting an inert gas into the glass tube to form an inert gas atmosphere; and iv) irradiating microwaves by heating the catalyst member by irradiating the microwaves onto the catalyst member such that the catalyst member is placed in a reduction reaction state.

The promoting method may further include: i) injecting steam and gas by injecting steam and an inert gas into the glass tube; and ii) discontinuing microwave irradiation by cooling the catalyst member by stopping the irradiation of the microwaves onto the catalyst member such that the catalyst member is placed in an oxidation reaction state.

In the step of injecting gas and the step of injecting steam and gas, the inert gas and the steam, respectively, may be brought into contact with the catalyst member via the plasma region when introduced into the glass tube.

In the step of forming a plasma, the plasma region may be formed at a position spaced apart from the catalyst member.

### Advantageous Effects

An apparatus for promoting a chemical reaction according to an embodiment of the present disclosure can produce hydrogen by reducing and oxidizing a catalyst member, which is a metal oxide, and performing water splitting under a relatively low temperature using microwaves and plasma.

### BRIEF DESCRIPTION OF THE DRAWINGS

FIG. 1 is a view showing a configuration of an apparatus for promoting a chemical reaction of a metal oxide catalyst according to an embodiment of the present disclosure and a reduction reaction state in which a catalyst member is reduced by the promoting apparatus.

FIG. 2 is a view showing an oxidation reaction state in which the catalyst member is oxidized by the promoting apparatus and a state in which hydrogen is generated by water splitting.

FIG. 3 is a view showing steps of a method for promoting a chemical reaction of a metal oxide catalyst according to an embodiment of the present disclosure.

### DETAILED DESCRIPTION

Hereinafter, various embodiments of the present disclosure will be described in detail with reference to the accompanying drawings so that those skilled in the art to which the present disclosure pertains can easily implement them. The present disclosure may be implemented in various different forms and is not limited to the embodiments described herein.

In order to clearly describe the present disclosure, parts irrelevant to the description are omitted, and the same or similar constituent elements are assigned the same reference numerals throughout the specification.

In addition, since the size and thickness of each component shown in the drawings are arbitrarily indicated for convenience of description, the present disclosure is not necessarily limited to those shown. In the drawings, the thicknesses are exaggerated to clearly express various layers and regions. Moreover, in the drawings, the thicknesses of some layers and regions are exaggerated for convenience of description.

Furthermore, throughout the specification, when a part "comprises, and/or includes" a certain constituent element, this means that other constituent elements are not excluded but may be further included unless otherwise stated.

Also, throughout the specification, the 'upper part,' 'top,' 'upper end,' or 'upper surface' of a constituent element indicates an end, part, top, or surface of the constituent element that is relatively on the upper side in the drawings, and the 'lower part,' 'bottom,' 'lower end,' or 'lower surface' of a constituent element indicates an end, part, bottom, or surface of the constituent element that is relatively on the lower side in the drawings.

Hereinafter, embodiments of the present disclosure will be described in detail with reference to the accompanying drawings.

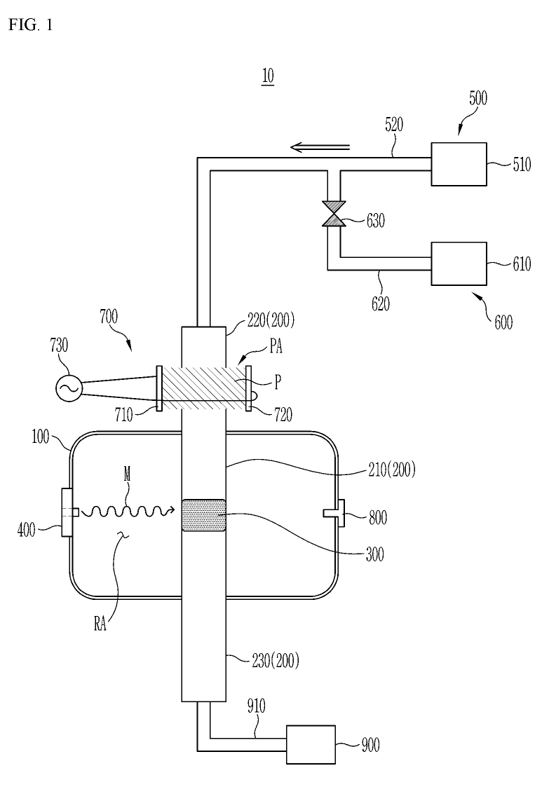

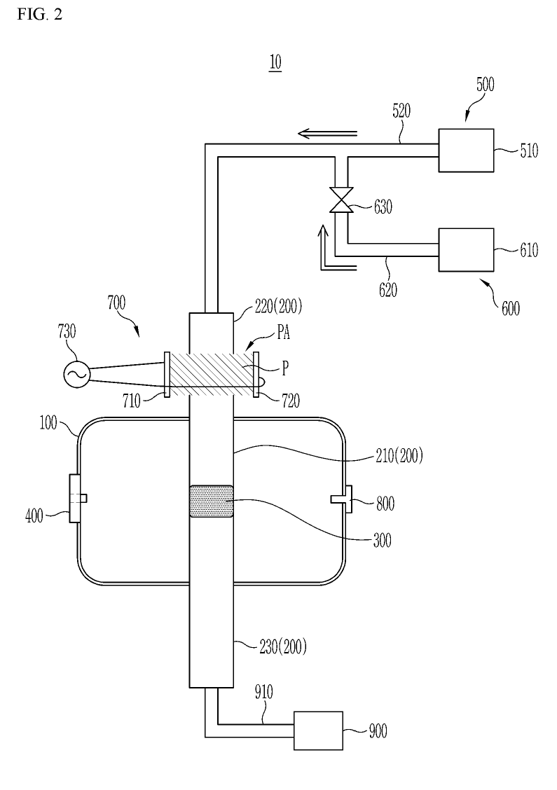

FIGS. 1 and 2 are views showing an apparatus (10) for promoting a chemical reaction of a metal oxide catalyst using microwaves and plasma (hereinafter referred to as a promoting apparatus (10)) according to an embodiment of the present disclosure. Specifically, FIG. 1 shows a reduction reaction state in which the catalyst member (300) is reduced by the promoting apparatus (10), and FIG. 2 shows an oxidation reaction state in which the catalyst member (300) is oxidized by the promoting apparatus (10) and a state in which hydrogen is generated by water splitting.

Referring to FIGS. 1 and 2, the promoting apparatus (10) can produce hydrogen by reducing and oxidizing the catalyst member (300), which is a metal oxide, and performing water splitting under a relatively low temperature using microwaves and plasma.

The promoting apparatus (10) may include a cavity resonator (100), a glass tube (200), a catalyst member (300), a microwave irradiation unit (400), a gas supply unit (500), a steam supply unit (600), a plasma unit (700), a thermometer (800), and a mass spectrometer (900).

The cavity resonator (100) is configured to resonate electromagnetic waves (for example, microwaves (M)) when the electromagnetic waves of a predetermined frequency are introduced therein. For example, when microwaves (M) are irradiated into the interior of the cavity resonator (100) by the microwave irradiation unit (400), the microwaves (M) may be resonated inside the cavity resonator (100). Meanwhile, a region where the microwaves (M) resonate inside the cavity resonator (100) may be defined as a resonance region (RA).

The cavity resonator (100) may be formed of a metal case with a hollow interior and has an inherent resonance frequency. The cavity resonator (100) utilizes the principle that energy is stored in the form of a standing wave of electromagnetic field therein, thus having high energy transfer efficiency.

Referring to FIGS. 1 and 2, the glass tube (200) extends in one direction and is installed in the cavity resonator (100) such that at least a portion thereof passes through the interior of the cavity resonator (100).

The glass tube (200) may include a resonance part (210), an inlet part (220), and an outlet part (230).

The resonance part (210) is disposed inside the cavity resonator (100). Further, the catalyst member (300) is disposed inside the resonance part (210). That is, the catalyst member (300) is disposed inside the resonance part (210) of the glass tube (200) on the resonance region (RA).

The inlet part (220) extends from one end (the upper end in FIG. 1) of the resonance part (210) to the upper outside of the cavity resonator (100). Inert gas and steam from the gas supply unit (500) may be introduced into the inlet part (220). In the inlet part (220), a plasma region (PA) is formed through which the inert gas and the steam pass, which will be described in detail later.

The outlet part (230) extends from the other end (the lower end in FIG. 1) of the resonance part (210) to the lower outside of the cavity resonator (100). Hydrogen generated from steam through the reduction reaction and oxidation reaction of the catalyst member (300) may be discharged through the outlet part (230).

The catalyst member (300) is formed of a metal oxide and is disposed inside the resonance part (210) of the glass tube (200). The catalyst member (300) may be placed in any one of a reduction reaction state and an oxidation reaction state. A detailed description of the reduction reaction state and the oxidation reaction state of the catalyst member (300) will be provided later.

The microwave irradiation unit (400) irradiates microwaves (M) onto the catalyst member (300) by passing them through the interior of the cavity resonator (100) to selectively heat the catalyst member (300). In this case, the microwave irradiation unit (400) irradiates the microwaves (M) onto the catalyst member (300) such that the frequency of the microwaves (M) corresponds to the inherent frequency of the cavity resonator (100). Accordingly, the microwaves (M) can selectively heat only the catalyst member (300) disposed inside the cavity resonator (100) and the glass tube (200).

The microwave irradiation unit (400) irradiates the microwaves (M) onto the catalyst member (300) so that the catalyst member (300) is placed in a reduction reaction state. For example, when the microwave irradiation unit (400) irradiates the microwaves (M) onto the catalyst member (300), the catalyst member (300) is heated, and a reduction reaction occurs in which a predetermined amount of oxygen is released from the catalyst member (300) (FIG. 1).

In this way, the microwave irradiation unit (400) selectively heats only the catalyst member (300) by passing the microwaves (M) through the interior of the cavity resonator (100), thereby causing a reduction reaction in which oxygen is released from the catalyst member (300) at a relatively low temperature (for example, about 200° C to 300° C).

The thermometer (800) measures the temperature of the catalyst member (300) when the microwaves (M) selectively heat the catalyst member (300). For example, the thermometer (800) may measure whether the catalyst member (300) heated by the microwaves (M) is heated within a normal temperature range. Such a thermometer (800) may include various thermometers such as a non-contact thermometer such as an infrared thermometer or a laser thermometer.

When the microwave irradiation unit (400) stops irradiating the microwaves (M) onto the catalyst member (300), the catalyst member (300) is cooled, and an oxidation reaction occurs in which a predetermined amount of oxygen (O₂) released by water splitting of steam supplied by the steam supply unit (600) is adsorbed onto the catalyst member (300) (FIG. 2).

Meanwhile, in this case, hydrogen (H₂) is generated from steam (H₂O). For example, while the catalyst member (300) is cooled, the steam (H₂O) is heated to generate oxygen (O₂) and hydrogen (H₂), the oxygen (O₂) is adsorbed onto the catalyst member (300), and the hydrogen (H₂) is introduced into the mass spectrometer (900) via the discharge channel (910) through the outlet part (230) of the glass tube (200).

Referring to FIGS. 1 and 2, the gas supply unit (500) selectively injects an inert gas into the glass tube (200). The gas supply unit (500) may include a gas supply part (510) for supplying an inert gas to the glass tube (200) and a gas channel (520) providing a path through which the inert gas flows from the gas supply part (510) to the glass tube (200). The inert gas may include argon (Ar) and helium (He). The gas supply unit (500) supplies the inert gas both when the catalyst member (300) is in the reduction reaction state and the oxidation reaction state.

The steam supply unit (600) selectively injects steam (H₂O) into the glass tube (200). For example, the steam supply unit (600) injects steam (H₂O) into the glass tube (200) such that the catalyst member (300) is placed in an oxidation reaction state in which oxygen (O₂) is adsorbed onto the catalyst member (300) (FIG. 2). Conversely, the steam supply unit (600) does not inject steam (H₂O) into the inlet tube when the catalyst member (300) is in a reduction reaction state in which oxygen (O₂) is released from the catalyst member (300) (FIG. 1).

The steam supply unit (600) may include a steam supply part (610), a steam channel (620), and an injection valve (630).

The steam supply part (610) supplies steam to the glass tube (200). The steam supply part (610) may supply steam at a ratio of, for example, about 20 vol%.

The steam channel (620) is connected to communicate with the gas channel (520) from the steam supply part (610).

The injection valve (630) is disposed in the steam channel (620) and can be opened and closed so that steam is selectively introduced from the steam supply part (610) into the gas channel (520).

For example, when the catalyst member (300) is in a reduction reaction state in which oxygen (O₂) is released from the catalyst member (300) heated by the irradiation of microwaves (M), the injection valve (630) is closed to block the steam (H₂O) from being introduced into the glass tube (200) through the gas channel (520) (FIG. 1).

Conversely, when the catalyst member (300) is to be placed in an oxidation reaction state, the injection valve (630) is opened to allow the steam (H₂O) to be introduced into the gas channel (520) (FIG. 2). The steam and the inert gas in the gas channel (520) are introduced into the glass tube (200) together. When the steam comes into contact with the catalyst member (300), the microwave irradiation unit (400) stops the irradiation of microwaves (M). Since the microwaves (M) are not irradiated onto the catalyst member (300), the catalyst member (300) is cooled while the steam (H₂O) is heated, and oxygen (O₂) and hydrogen (H₂) are generated from the steam (H₂O). In this case, the oxygen (O₂) is adsorbed onto the catalyst member (300) to be placed in an oxidation reaction state, and the hydrogen (H₂) is introduced into the mass spectrometer (900) via the discharge channel (910) through the outlet part (230) of the glass tube (200).

In this way, hydrogen can be generated from steam by repeatedly performing the reduction reaction and the oxidation reaction of the catalyst member (300).

Referring to FIGS. 1 and 2, the catalyst member (300) may be placed in a reduction reaction state in which the catalyst member (300) is heated by being irradiated with microwaves (M) so that a predetermined amount of oxygen (O₂) is released from the catalyst member (300) and the catalyst member (300) is reduced (FIG. 1).

Conversely, the catalyst member (300) may be placed in an oxidation reaction state in which the catalyst member (300) is cooled by not being irradiated with microwaves (M) so that a predetermined amount of oxygen (O₂) released by water splitting is adsorbed onto the catalyst member (300) and the catalyst member (300) is oxidized (FIG. 2). In such an oxidation reaction state, hydrogen is generated from steam.

That is, as the catalyst member (300) is cooled, oxygen (O₂) and hydrogen (H₂) are generated from the steam (H₂O), the generated oxygen (O₂) is adsorbed onto the catalyst member (300) to cause a reduction reaction, and the generated hydrogen (H₂) is introduced into the mass spectrometer (900) via the discharge channel (910) through the outlet part (230) of the glass tube (200).

Such a catalyst member (300) may include magnetite (Fe₃O₄), nickel ferrite (NiFe₂O₄), cobalt ferrite (CoFe₂O₄), magnesium ferrite (MgFe₂O₄), mixed metal ferrite ((MgNiCo)₀.₇₅Fe₀.₂₅O₁.₂), cerium dioxide (CeO₂), gadolinium-doped cerium dioxide (Gd₀.₂Ce₀.₈O₂), lanthanum strontium oxide (LaSrO₃), calcium titanate (CaTiO₃), barium manganate (BaMnO₃), and strontium titanate (SrTiO₃).

Magnetite (Fe₃O₄), nickel ferrite (NiFe₂O₄), cobalt ferrite (CoFe₂O₄), magnesium ferrite (MgFe₂O₄), and mixed metal ferrite ((MgNiCo)₀.₇₅Fe₀.₂₅O₁.₂) are ferrite-based oxides. Such ferrite-based oxides have a somewhat slow reaction rate, but reduction and oxidation reactions can occur at relatively low temperatures.

Cerium dioxide (CeO₂) and gadolinium-doped cerium dioxide (Gd₀.₂Ce₀.₈O₂) are fluorite-based oxides. Such fluorite-based oxides have a fast reaction rate and ensure stability at high temperatures.

Lanthanum strontium oxide (LaSrO₃), calcium titanate (CaTiO₃), barium manganate (BaMnO₃), and strontium titanate (SrTiO₃) are perovskite-based oxides. Such perovskite-based oxides also have a somewhat slow reaction rate, but reduction and oxidation reactions can occur at relatively low temperatures.

Referring to FIGS. 1 and 2, the plasma unit (700) may generate plasma (P) to form a plasma region (PA) surrounding the inlet part (220) of the glass tube (200) so as to penetrate the inlet part (220) with the plasma (P).

The inert gas and the steam may contact the catalyst member (300) via the plasma region (PA) when introduced into the glass tube (200). In this case, the plasma (P) can further activate the inert gas by lowering the activation energy required when the reduction reaction and the oxidation reaction occur in the catalyst member (300). In addition, the plasma (P) can increase the activity of water molecules by weakening the bonds of water molecules in the steam.

For example, the inert gas supplied from the gas supply unit (500) is introduced into the inlet part (220) of the glass tube (200) and is further activated while passing through the plasma region (PA). Accordingly, the activated inert gas further promotes the reduction reaction in which oxygen is released from the catalyst member (300) and the oxidation reaction in which oxygen is adsorbed onto the catalyst member (300).

In addition, the steam supplied from the steam supply unit (600) is introduced into the inlet part (220) of the glass tube (200) together with the inert gas and is further activated as its bonding bonds are weakened while passing through the plasma region (PA). Accordingly, the activated steam further promotes the reaction of generating oxygen and hydrogen while the catalyst member (300) is cooled, further promotes the reduction reaction in which the generated oxygen is adsorbed onto the catalyst member (300), and also increases the generation rate of hydrogen generated from the steam.

The plasma unit (700) is operated to form the plasma region (PA) both when the catalyst member (300) is in the reduction reaction state and the oxidation reaction state. That is, the plasma unit (700) always forms the plasma region (PA) so that the inert gas and the steam pass through it, so that the plasma (P) increases the activity of the inert gas and the activity of the steam to promote the reduction reaction and the oxidation reaction of the catalyst member (300) and the production of hydrogen.

Meanwhile, as the plasma unit (700), it is preferable to use a dielectric barrier discharge (DBD) type device, but the embodiment of the present disclosure is not limited thereto, and various devices capable of generating plasma (P) may be used.

Referring to FIGS. 1 and 2, the plasma unit (700) forms the plasma region (PA) at a position spaced apart from the resonance region (RA) and the catalyst member (300). That is, the plasma unit (700) forms the plasma region (PA) at the inlet part (220) of the glass tube (200), which is a position spaced apart from the resonance region (RA) of the cavity resonator (100) and the catalyst member (300). This is to prevent the plasma (P) and the microwaves (M) from disturbing each other.

The plasma unit (700) includes a first metal electrode (710), a second metal electrode (720), and a power application unit (730).

The first metal electrode (710) is disposed spaced apart from one side of the inlet part (220) of the glass tube (200).

The second metal electrode (720) is disposed spaced apart from the other side of the inlet part (220) of the glass tube (200). That is, the inlet part (220) of the glass tube (200) is positioned between the first metal electrode (710) and the second metal electrode (720).

The power application unit (730) applies power to the first metal electrode (710) and the second metal electrode (720) such that the plasma region (PA) is formed at the inlet part (220).

That is, the plasma unit (700) forms the plasma region (PA) at the inlet part (220) of the glass tube (200), which is a position spaced apart from the resonance region (RA) and the catalyst member (300). Accordingly, the inert gas and the steam can be introduced into the glass tube (200) while passing through the plasma region (PA), and the plasma region (PA) can be formed at a position spaced apart from the resonance region (RA) of the cavity resonator (100) and the catalyst member (300).

Referring to FIGS. 1 and 2, the mass spectrometer (900) can measure the mass of hydrogen generated from steam. The mass spectrometer (900) is a device that measures the mass of a substance as a mass-to-charge ratio. Meanwhile, the mass spectrometer (900) can also measure the mass of oxygen, so that it is also possible to determine whether oxygen is adsorbed onto the catalyst member (300) in a normal range.

Meanwhile, the production efficiency of hydrogen produced by the promoting apparatus (10) according to the present disclosure can be calculated as the amount of hydrogen produced / energy input, and it was confirmed through actual experimental results that a considerably high value of hydrogen production efficiency appeared.

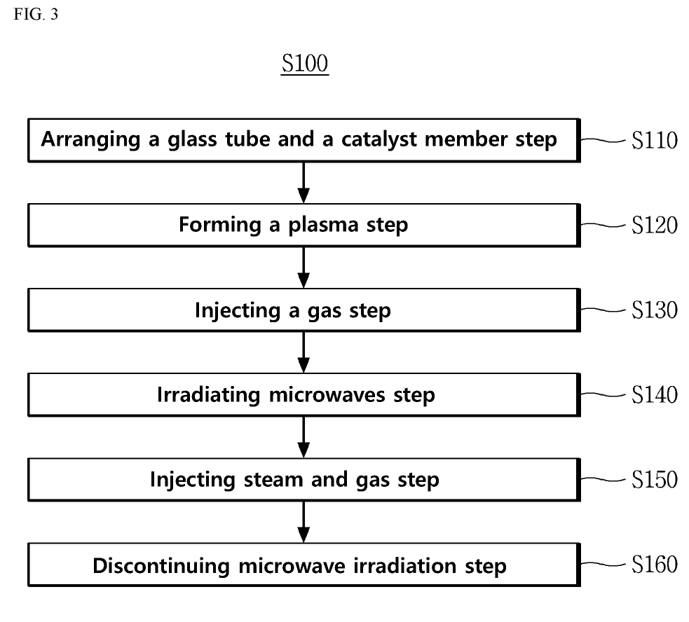

FIG. 3 is a view showing steps of a method (S100) for promoting a chemical reaction of a metal oxide catalyst (hereinafter referred to as a promoting method (S100)) according to an embodiment of the present disclosure.

Referring to FIG. 3, the promoting method (S100) is a method for promoting a chemical reaction of a metal oxide catalyst using the promoting apparatus (10).

The promoting method (S100) may include a step of arranging a glass tube and a catalyst member (S110), a step of injecting gas (S120), a step of forming a plasma (S130), a step of irradiating microwaves (S140), a step of injecting steam and gas (S150), and a step of discontinuing microwave irradiation (S160).

The step of arranging a glass tube and a catalyst member (S110) is a step of positioning the glass tube (200) such that a portion of the glass tube (200) passes through the interior of the cavity resonator (100) that resonates electromagnetic waves, and disposing the catalyst member (300) inside the glass tube (200).

The step of forming a plasma (S130) is a step of forming a plasma region (PA) at a portion of the glass tube (200). That is, the plasma unit (700) is used to form the plasma region (PA) surrounding the inlet part (220) of the glass tube (200) so as to penetrate the inlet part (220) with the plasma (P).

In the step of forming a plasma (S130), the plasma region (PA) is formed at a position spaced apart from the catalyst member (300). That is, the plasma region (PA) is formed at the inlet part (220) of the glass tube (200), which is a position spaced apart from the resonance region (RA) of the cavity resonator (100) and the catalyst member (300), so that the plasma (P) and the microwaves (M) do not disturb each other.

The step of injecting gas (S120) is a step of injecting an inert gas into the glass tube (200) to form an inert gas atmosphere. That is, argon (Ar) or helium (He) is injected into the glass tube (200) using the gas supply unit (500) so as to contact the catalyst member (300).

In addition, in the step of injecting gas (S120), the inert gas is brought into contact with the catalyst member (300) so as to pass through the plasma region (PA) when introduced into the glass tube (200) so as to activate the inert gas.

The step of irradiating microwaves (S140) is a step of heating the catalyst member (300) by irradiating microwaves (M) onto the catalyst member (300) such that the catalyst member (300) is placed in a reduction reaction state. That is, the microwaves (M) are irradiated onto the catalyst member (300) with the microwave irradiation unit (400) to heat the catalyst member (300), thereby causing a reduction reaction in which oxygen is released from the catalyst member (300).

As such, when the reduction reaction of the catalyst member (300) is completed, the following oxidation reaction of the catalyst member (300) is performed.

The step of injecting steam and gas (S150) is a step of injecting steam and an inert gas into the glass tube (200). That is, the injection valve (630) of the steam supply unit (600) is opened to allow the steam to flow into the glass tube (200) together with the inert gas.

In addition, in the step of injecting steam and gas (S150), the steam is brought into contact with the catalyst member (300) so as to pass through the plasma region (PA) when introduced into the glass tube (200) so as to weaken the bonds of the steam and activate it.

The step of discontinuing microwave irradiation (S160) is a step of cooling the catalyst member (300) by stopping the irradiation of microwaves (M) onto the catalyst member (300) such that the catalyst member (300) is placed in an oxidation reaction state.

For example, when the steam contacts the catalyst member (300), the irradiation of microwaves (M) by the microwave irradiation unit (400) is immediately stopped, and when the catalyst member (300) is cooled because the microwaves (M) are not irradiated onto the catalyst member (300), the steam (H₂O) is heated to generate oxygen (O₂) and hydrogen (H₂). In this case, the oxygen (O₂) is adsorbed onto the catalyst member (300) to be placed in an oxidation reaction state, and the hydrogen (H₂) is introduced into the mass spectrometer (900) via the discharge channel (910) through the outlet part (230) of the glass tube (200).

In this way, when the reduction reaction of the catalyst member (300) is completed, hydrogen (H₂) can be produced by continuously repeating the reduction reaction and the oxidation reaction thereafter.

Although the embodiments of the present disclosure have been described in detail above, the scope of the present disclosure is not limited thereto, and various modifications and improvements by those skilled in the art using the basic concept of the present disclosure defined in the following claims also belong to the scope of the present disclosure.

### DESCRIPTION OF REFERENCE NUMERALS

10: Apparatus for promoting a chemical reaction of a metal oxide catalyst

100: Cavity resonator

200: Glass tube

210: Resonance part

220: Inlet part

230: Outlet part

300: Catalyst member

400: Microwave irradiation unit

500: Gas supply unit

510: Gas supply part

520: Gas channel

600: Steam supply unit

610: Steam supply part

620: Steam channel

630: Injection valve

700: Plasma unit

710: First metal electrode

720: Second metal electrode

730: Power application unit

800: Thermometer

900: Mass spectrometer

910: Discharge channel

M: Microwave

RA: Resonance region

P: Plasma

PA: Plasma region

1. An apparatus for promoting a chemical reaction of a metal oxide catalyst using microwaves and plasma, comprising:
a cavity resonator configured to resonate electromagnetic waves of a predetermined frequency when the electromagnetic waves are introduced therein;
a glass tube, at least a portion of which passes through an interior of the cavity resonator;
a catalyst member disposed inside the glass tube, the catalyst member being a metal oxide;
a microwave irradiation unit for irradiating microwaves onto the catalyst member by passing the microwaves through the interior of the cavity resonator so as to selectively heat the catalyst member;
a gas supply unit for selectively injecting an inert gas into the glass tube; and
a steam supply unit for selectively injecting steam into the glass tube.

2. The apparatus for promoting a chemical reaction of a metal oxide catalyst using microwaves and plasma of claim 1, wherein: the catalyst member is placed in any one state of: a reduction reaction state in which the catalyst member is heated by being irradiated with the microwaves such that a predetermined amount of oxygen is released from the catalyst member and the catalyst member is reduced; and an oxidation reaction state in which the catalyst member is cooled by not being irradiated with the microwaves such that a predetermined amount of oxygen released by water splitting is adsorbed onto the catalyst member and the catalyst member is oxidized, wherein hydrogen is generated from the steam when the catalyst member is in the oxidation reaction state.

3. The apparatus for promoting a chemical reaction of a metal oxide catalyst using microwaves and plasma of claim 2, further comprising: a plasma unit for generating plasma to form a plasma region surrounding a portion of the glass tube so as to penetrate the portion of the glass tube with the plasma, wherein the inert gas and the steam contact the catalyst member via the plasma region when introduced into the glass tube.

4. The apparatus for promoting a chemical reaction of a metal oxide catalyst using microwaves and plasma of claim 3, wherein: a region where the microwaves resonate inside the cavity resonator is defined as a resonance region; the catalyst member is disposed inside the glass tube on the resonance region; and the plasma unit forms the plasma region at a position spaced apart from the resonance region.

5. The apparatus for promoting a chemical reaction of a metal oxide catalyst using microwaves and plasma of claim 3, wherein: the microwave irradiation unit irradiates the microwaves onto the catalyst member such that the catalyst member is placed in the reduction reaction state; and the steam supply unit injects the steam into the glass tube such that the catalyst member is placed in the oxidation reaction state.

6. The apparatus for promoting a chemical reaction of a metal oxide catalyst using microwaves and plasma of claim 3, wherein the glass tube comprises: a resonance part disposed inside the cavity resonator; an inlet part extending from one end of the resonance part to an outside of the cavity resonator, through which the inert gas and the steam are introduced from the gas supply unit; and an outlet part extending from the other end of the resonance part to the outside of the cavity resonator, through which hydrogen is discharged.

7. The apparatus for promoting a chemical reaction of a metal oxide catalyst using microwaves and plasma of claim 6, wherein: the catalyst member is disposed inside the resonance part; and the plasma unit forms the plasma region at the inlet part.

8. The apparatus for promoting a chemical reaction of a metal oxide catalyst using microwaves and plasma of claim 7, wherein the plasma unit comprises: a first metal electrode disposed spaced apart from one side of the inlet part; a second metal electrode disposed spaced apart from the other side of the inlet part; and a power application unit for applying power to the first metal electrode and the second metal electrode such that the plasma region is formed at the inlet part.

9. The apparatus for promoting a chemical reaction of a metal oxide catalyst using microwaves and plasma of claim 1, wherein the gas supply unit comprises: a gas supply part for supplying the inert gas to the glass tube; and a gas channel providing a path through which the inert gas flows from the gas supply part to the glass tube.

10. The apparatus for promoting a chemical reaction of a metal oxide catalyst using microwaves and plasma of claim 9, wherein the steam supply unit comprises: a steam supply part for supplying the steam to the glass tube; a steam channel connected to communicate with the gas channel from the steam supply part; and an injection valve disposed in the steam channel and configured to be opened and closed such that the steam is selectively introduced from the steam supply part into the gas channel.

11. The apparatus for promoting a chemical reaction of a metal oxide catalyst using microwaves and plasma of claim 1, wherein the catalyst member comprises: magnetite (Fe₃O₄), nickel ferrite (NiFe₂O₄), cobalt ferrite (CoFe₂O₄), magnesium ferrite (MgFe₂O₄), mixed metal ferrite ((MgNiCo)₀.₇₅Fe₀.₂₅O₁.₂), cerium dioxide (CeO₂), gadolinium-doped cerium dioxide (Gd₀.₂Ce₀.₈O₂), lanthanum strontium oxide (LaSrO₃), calcium titanate (CaTiO₃), barium manganate (BaMnO₃), and strontium titanate (SrTiO₃).

12. A method for promoting a chemical reaction of a metal oxide catalyst using the apparatus for promoting a chemical reaction according to claim 1, the method comprising: arranging a glass tube and a catalyst member by positioning the glass tube such that a portion of the glass tube passes through an interior of a cavity resonator that resonates electromagnetic waves, and disposing the catalyst member inside the glass tube; forming a plasma by forming a plasma region at a portion of the glass tube; injecting a gas by injecting an inert gas into the glass tube to form an inert gas atmosphere; and irradiating microwaves by heating the catalyst member by irradiating the microwaves onto the catalyst member such that the catalyst member is placed in a reduction reaction state.

13. The method for promoting a chemical reaction of a metal oxide catalyst of claim 12, further comprising: injecting steam and gas by injecting steam and an inert gas into the glass tube; and discontinuing microwave irradiation by cooling the catalyst member by stopping the irradiation of the microwaves onto the catalyst member such that the catalyst member is placed in an oxidation reaction state.

14. The method for promoting a chemical reaction of a metal oxide catalyst of claim 13, wherein: in the step of injecting gas and the step of injecting steam and gas, the inert gas and the steam, respectively, are brought into contact with the catalyst member via the plasma region when introduced into the glass tube.

15. The method for promoting a chemical reaction of a metal oxide catalyst of claim 14, wherein: in the step of forming a plasma, the plasma region is formed at a position spaced apart from the catalyst member.
